(19) United States
(12) Patent Application Publication
(10) Pub. No.: US 2006/0063306 A1
(43) Pub. Date: Mar. 23, 2006

(54) Semiconductor package having a heat slug and manufacturing method thereof

(76) Inventor: Ki-Won Choi, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/233,949

(22) Filed: Sep. 23, 2005

(30) Foreign Application Priority Data
Sep. 23, 2004 (KR) 2004-76465

(51) Int. Cl. H01L 21/50

(52) U.S. Cl. 438/110

(57) ABSTRACT

In one embodiment, a circuit substrate strip includes molding blocks composed of a plurality of circuit substrate unit areas. An integrated circuit chip is attached onto each circuit substrate unit area and connected electrically thereto and a heat slug is attached thereon. Resin sealant is applied on the molding blocks by group molding and the cover of the heat slug is exposed out of the upper surface of the resin sealant. At each corner of the circuit substrate unit area, a supporter base is formed. Supporters extending downwards from the four corners of the cover are connected onto a supporter base. After formation of solder balls, the circuit substrate unit areas are separated into individual semiconductor packages by cutting the circuit substrate strip.

### CROSS REFERENCE TO RELATED APPLICATIONS

This U.S. non-provisional application claims priority and benefit of Korean Patent Application No. 2004-76465, filed on Sep. 23, 2004, the entire contents of which are herein incorporated by reference.

### BACKGROUND OF THE INVENTION

1. Field of the Invention

The invention relates to semiconductor packaging technology and, more particularly, to a structure of ball grid array (BGA) package having heat slug and a production method thereof.

2. Description of the Prior Art

In order to use an integrated circuit device fabricated from a semiconductor wafer in electronic products, the integrated circuit device is separated into a unit chip by cutting and then assembled in a package. A semiconductor package physically supports the integrated circuit chip, protects it from the influence of the external environment, provides electrical connections to the integrated circuit chip, and dissipates heat generated from the integrated circuit chip outwards. Nowadays, the importance of the packaging technology is increasing because packaging quality has a great influence on price, performance, and reliability of the semiconductor product.

On the other hand, a trend in electronic products using semiconductor packages is moving toward smaller size. Therefore, it is inevitable that the size of the semiconductor packages having equivalent performances should also be reduced. Accordingly, heat dissipation, one of the essential functions of the package, is a growing concern. The function of heat dissipation is growing more important, especially, in the newer types of packages that have a large number of input/output pins, high capacity, and high operating speed.

Recently, the application range for a ball grid array package, a typical package form having a plurality of solder balls are arrayed on one side of a circuit substrate, has been expanding gradually. Generally, in the prior art, the aforementioned heat dissipation problem is solved by using a heat slug (also known as heat sink or heat spreader) with the ball grid array package.

FIG. 1 illustrates an example of a semiconductor package equipped with a heat slug in accordance with the prior art. Referring to FIG. 1, in a semiconductor package 10 of the ball grid array type, solder balls 11 acting as external terminals are formed regularly underneath the circuit substrate 13. An integrated circuit chip 12 is located in a central empty space of the circuit substrate 13 and the active surface of the chip faces toward the lower direction, i.e. the downward arrangement type. The active surface of the integrated circuit chip 12 is then connected electrically to the circuit substrate 13 through metal wires 14. The integrated circuit chip 12 and the metal wires 14 are sealed with resin sealant 15 and thus protected from the influence of the external environment. A heat slug 16 is attached both on the backside of the integrated circuit chip 12 and on the top of the circuit substrate 13.

In the semiconductor package 10 illustrated in FIG. 1, an improvement of heat dissipation using the heat slug 16 may be expected. However, this type of the package 10 has a downward arrangement and thus solder balls cannot be formed in the region occupied by the integrated circuit chip. Accordingly, reduction of package size is limited, and thereby does not follow the recent trend of technology.

FIG. 2 illustrates another example of a semiconductor package having a heat slug in accordance with the prior art. The semiconductor package shown in FIG. 2 is disclosed in U.S. Pat. No. 5,977,626.

In a semiconductor package 20 shown in FIG. 2, solder balls 21 acting as external terminals of the package, are evenly formed in the full range of the lower surface of a circuit substrate 23. An integrated circuit chip 22 is attached in the center of the circuit substrate 23 so that active surface faces toward the top of the package 20. Accordingly, the active surface of the integrated circuit chip 22 is electrically connected to the upper surface of the circuit substrate 23 through metal wires 24. The integrated circuit chip 22 and the metal wires 24 are sealed with resin sealant 25, and thus protected from the influence of the external environment. A heat slug 26 is inserted into the resin sealant 25, so that the upper surface of the heat slug 26 is exposed to the outside of the resin sealant 25 and its lower surface is in contact with the integrated circuit chip 22 and the circuit substrate 23.

In the prior art, the heat slug 26 of the semiconductor package 20 is located in the resin sealant 25. Accordingly, the heat slug 26 is inserted into a mold first and the circuit substrate 23 is placed upside down on the top of the mold, then the resin sealant 25 is applied. This type of production method, which utilizes an individual molding method, has a disadvantage in the productivity. Even though a plurality of packages may be manufactured simultaneously in the form of strip so as to improve the productivity, the heat slug 26 has to be inserted individually into every mold and the resin sealant 25 also has to be applied into the mold one-by-one. Therefore, improvement of the productivity is still limited. Moreover, as shown in FIG. 2, the resin sealant 25 is not applied to space 27 on the circuit substrate 23. Accordingly, because the size of the heat slug 26 is smaller than that of the package 20, optimum heat dissipation may not be expected.

In addition to the aforementioned two examples, other prior art examples of semiconductor packages having heat slugs are disclosed in U.S. Pat. Nos. 6,433,420 and 6,462,405, and U.S. Pub. Nos. 2001/0019181, 2002/0053724, 2002/0079593 and 2003/0025215. However, all of the packages disclosed in the above patents and applications adopt the same means to attach the heat slug individually in each package unit as explained above. Therefore, the productivity and the efficiency of heat dissipation are comparatively unsatisfactory.

### SUMMARY OF THE INVENTION

In one embodiment, the production method of semiconductor packages having a heat slug in accordance with the invention comprises providing circuit substrate strip having an upper surface, a lower surface and molding blocks formed by a plurality of circuit substrate unit areas, attaching integrated circuit chips onto the upper surface of each circuit substrate unit area and electrically connecting the integrated circuit chips thereto, attaching a heat slug onto the upper surface of each circuit substrate unit area, applying resin sealant onto the upper surface of the molding blocks by a group molding process so as to seal the integrated circuit chip and to have a part of the heat slug exposed outwards, forming solder balls onto the lower surface of each circuit substrate unit area, and separating the individual semiconductor package formed on each circuit substrate unit area by cutting the circuit substrate strip.

The invention also provides semiconductor packages having a heat slug in accordance with the aforementioned manufacturing method.

In one aspect of the invention, the heat slug can include a flat cover part and a leg-type supporter extending from each corner of the cover in the downward direction. The cover is exposed on the top of the resin sealant and the supporters may be sealed by the resin sealant. Further, the cover can have almost the same size as the circuit substrate unit area. A supporter base may be formed at each corner of the circuit substrate unit. Each supporter adjacent to the supporter base is connected to the supporter base. The connection between supporter and supporter base can be made by any one of soldering, conductive epoxy or anisotropic conductive material. The supporter base can also be connected to a ground pattern of the circuit substrate unit area. Alternatively, the heat slug can include a projection which protrudes from the lower surface of the cover and links the cover downwards to the integrated circuit chip.

In the structure and manufacturing method of semiconductor packages having a heat slug in accordance with another aspect of the invention, two or more molding blocks can be arrayed at regular intervals. A semiconductor package can also include two or more integrated circuit chips arranged vertically or horizontally in the present invention. Electrical connections of the integrated circuit chip can be made with a metal wire or a metal bump. The solder balls can be formed by means of flux application, solder balls attachment and reflow. The circuit substrate strip can be divided into individual packages by a sawing blade or a laser.

### BRIEF DESCRIPTION OF THE DRAWINGS

The above and other features and advantages of embodiments of the invention will become readily apparent by reference to the following detailed description when considered in conjunction with the accompanying drawings.

FIG. 1 is a cross-sectional view showing an example of a semiconductor package having a heat slug in accordance with the prior art.

FIG. 2 is a cross-sectional view showing another example of a semiconductor package having a heat slug in accordance with the prior art.

FIGS. 3 to 7 are views showing a manufacturing method of a semiconductor package having a heat slug in accordance with the embodiments of the present invention.

FIG. 3 is a schematic top view of a circuit substrate strip, which provides batch production of package by group molding.

FIG. 4A is a top view showing integrated circuit chips and heat slugs attached on the circuit substrate strip.

FIG. 4B is a cross-sectional view showing the integrated circuit chips and the heat slugs attached on the circuit substrate strip.

FIG. 5 is a perspective view showing a heat slug structure.

FIG. 6 is a cross-sectional view showing a molding process.

FIG. 7 is a cross-sectional view showing solder ball formation and individual package separation process.

FIG. 8 is a cross-sectional view showing an embodiment of a semiconductor package having a heat slug in accordance with the present invention.

FIG. 9 is a cross-sectional view showing another embodiment of a semiconductor package having a heat slug in accordance with the present invention.

FIG. 10 is a cross-sectional view showing an embodiment of a semiconductor package having a heat slug in accordance with the present invention.

FIG. 11 is a cross-sectional view showing another embodiment of a semiconductor package having a heat slug in accordance with the present invention.

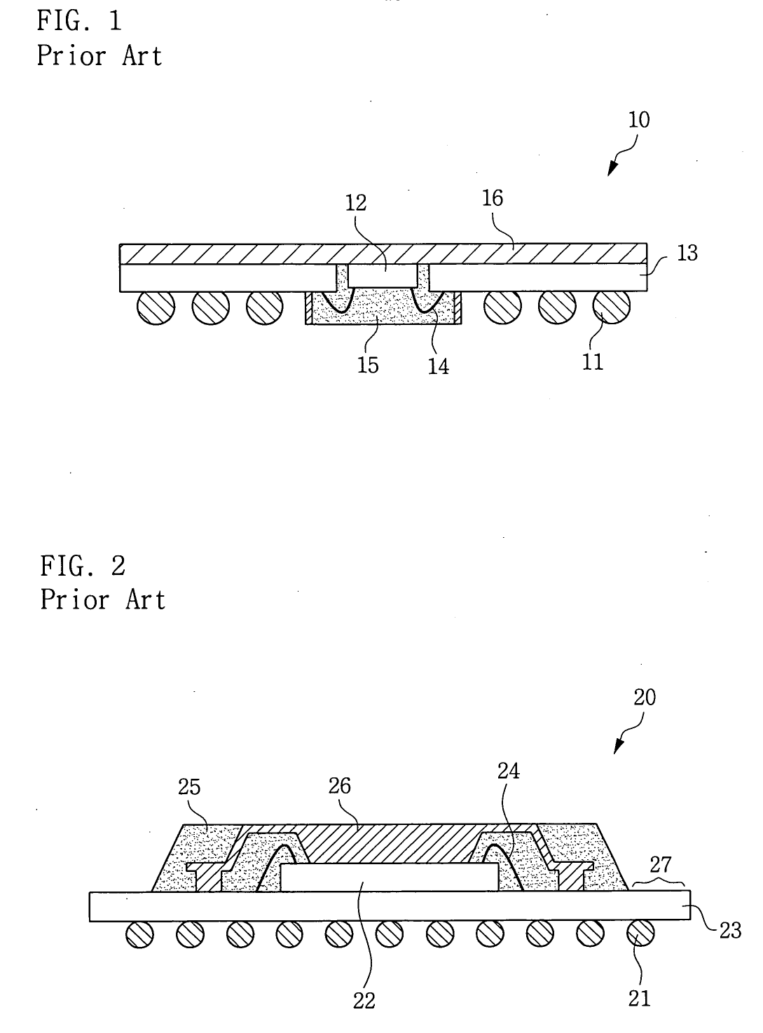

### DETAILED DESCRIPTION OF THE PREFERRED EMBODIMENTS

The invention will be described below with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In the explanation of the embodiments, technical contents that are made public and have no direct relation to the present invention are not shown. This is not to blur but rather to express the main points of the present invention by omitting unnecessary details.

For the same purpose, in the accompanying drawings some components are exaggerated, omitted, or outlined in brief and the dimensions of each component are not always shown in the same proportion to the original size. The same reference number is given to the same or corresponding component in the drawings. It will be understood that when an element such as a layer, a region or a substrate is referred to as being “on” or “onto” another element, it can be directly on the other element or intervening elements may also be present.

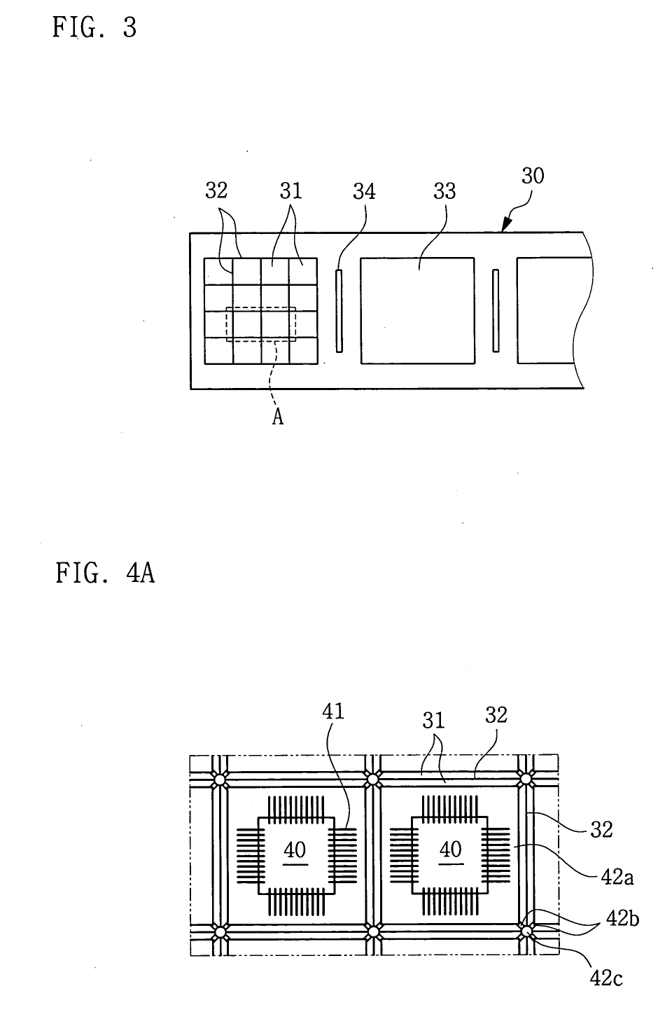

FIGS. 3 to 7 illustrate a production method of semiconductor packages having a heat slug in accordance with embodiments of the invention. The structure of the semiconductor package will be understood clearly through the following description of the manufacturing method.

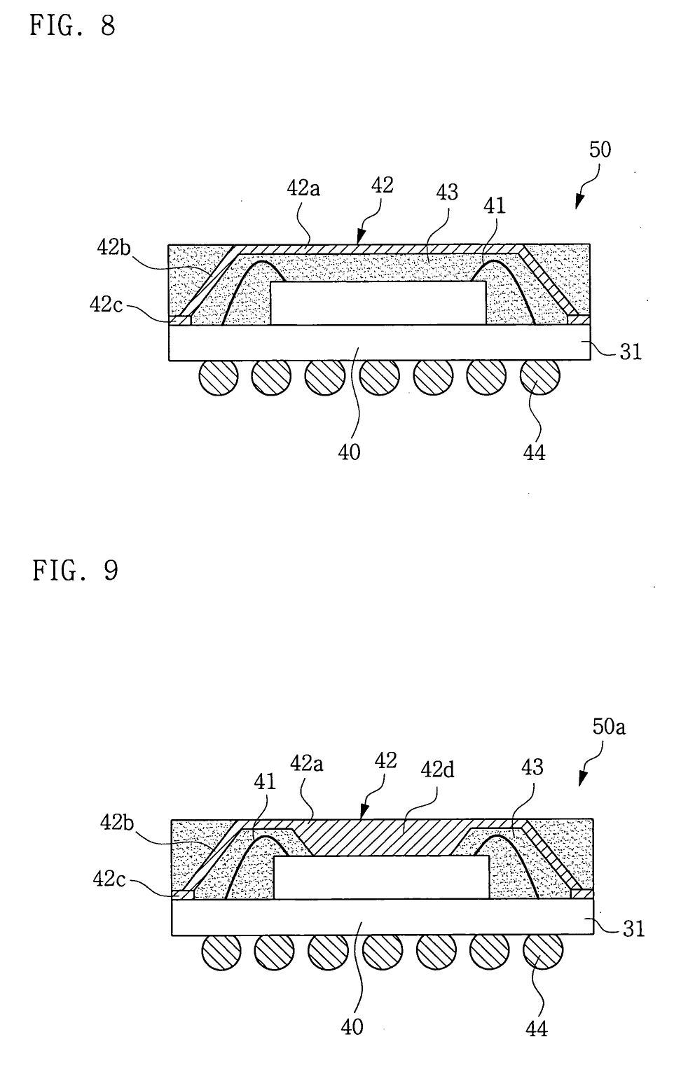

FIG. 3 is a schematic top view of a circuit substrate strip 30, which is utilized for the batch production of the packages by a group molding method. As shown in FIG. 3, the circuit substrate strip 30 includes molding blocks 33 on which a plurality of unit areas 31 are arranged in the form of a matrix. Several molding blocks are arrayed on the circuit substrate strip at regular intervals. Each circuit substrate unit area 31 corresponds to the circuit substrate 31 (in FIG. 8) included in the final structure of an individual package 50 (in FIG. 8). In addition, each molding block of the circuit substrate is molded as one group in the molding process.

Each circuit substrate unit area 31 is divided along vertical and horizontal cutting lines 32, and a slot 34 is formed between adjacent circuit substrate molding blocks 33. The cutting lines 32 can be actually drawn on the circuit substrate. Alternatively, they may be substituted by identification holes at the four corners of the circuit substrate unit area 31. A specified pattern of circuit is formed on the circuit substrate strip 30; however, it is not shown in the drawing to avoid complication of the drawing.

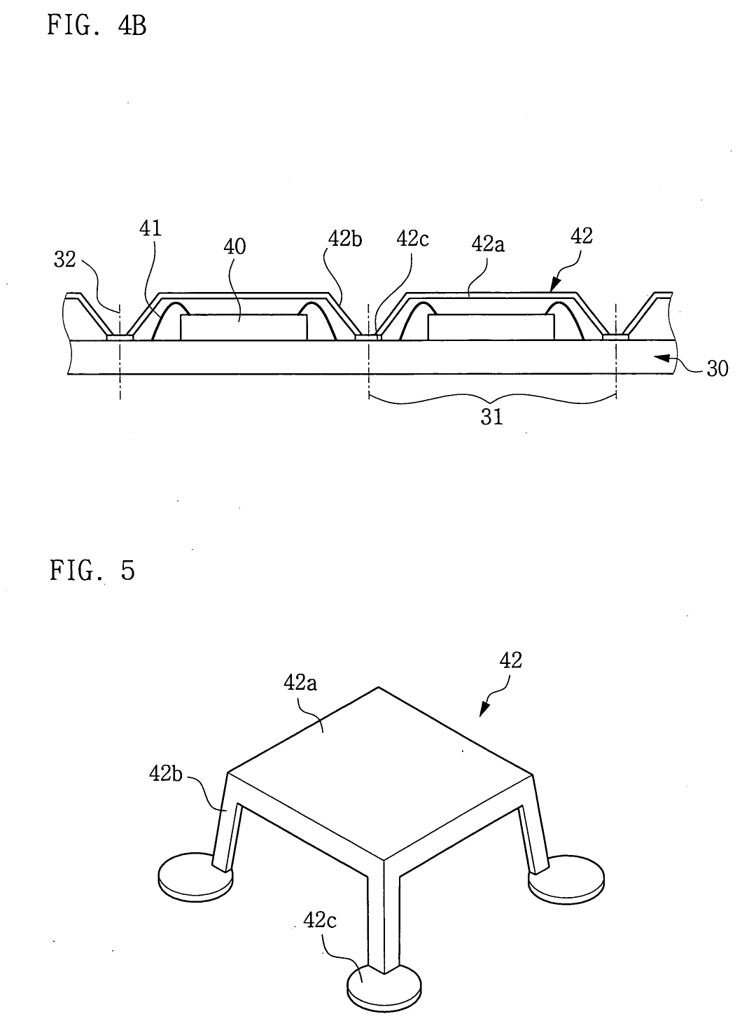

FIGS. 4A and 4B are top and cross-sectional views illustrating integrated circuit chips 40 and heat slugs 42 attached on the circuit substrate strip 30. FIGS. 4A and 4B show an enlarged view of the part “A” in FIG. 3. As shown in FIGS. 4A and 4B, the integrated circuit chip 40 is attached onto each circuit substrate unit area 31. The backside of the integrated circuit chip 40 is attached onto the circuit substrate 30 by an adhesive (not shown), and the active surface of the integrated circuit chip faces upward. Subsequently, an input/output pad (not shown) formed on the active surface of the integrated circuit chip 40 is connected electrically to the circuit pattern (not shown) on the circuit substrate 30 through metal wires 41.

The heat slug 42 is attached onto the circuit substrate unit area 31 on which the integrated circuit chip is already placed. The heat slug 42 can be made of a metal having high thermal conductivity. In the embodiment shown in FIG. 5, the heat slug 42 comprises a cover 42a, supporter 42b and supporter base 42c. The cover 42a has a flat surface and almost the same size as the circuit substrate unit area 31. The supporter 42b is formed as a shape of four legs extending from each corner of the cover 42a. The supporter base 42c, coupled with the bottom tip of supporter 42b, has a flat disc shape. However, the shape of the heat slug is not limited to the embodiment shown in the drawing.

A supporter base 42c is located at each of the four corners of the circuit substrate unit area 31, in other words at each intersecting point of cutting lines 32. The supporter base 42c can be prepared as a part of the circuit pattern on the circuit substrate 30 during circuit patterning or as a part of the heat slug 42. Thus, the supporter base 42c can be connected to a ground pattern in the circuit pattern of circuit substrate strip 30 or prepared as a part of the ground pattern. Each supporter 42b from four heat slugs adjacent to the supporter base 42c is connected to the supporter base. Any one of soldering, conductive epoxy or anistropic conductive material can be utilized for the connection between the supporter base 42c and the supporter 42b.

As described above, the structure of the heat slug 42, where supporters 42b from the four corners of the cover 42a are connected to the circuit substrate through the supporter base 42c, is designed to support the heat slug with a minimum force, and also not to interfere with the flow of molding resin in the subsequent molding process.

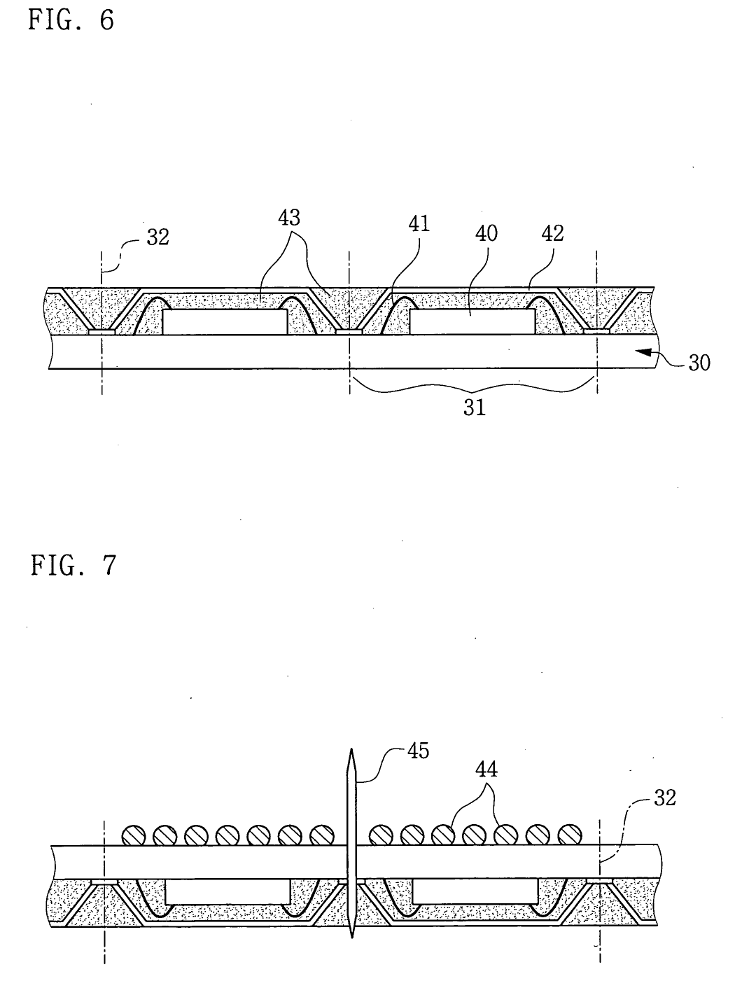

FIG. 6 illustrates a cross-sectional view of a group molding step. Referring to FIG. 6, the heat slug 42 is attached on each circuit substrate unit area 31. Resin sealant 43 is applied onto each molding block 33 (in FIG. 3) of the circuit substrate strip 30 by the group molding process. As an example, epoxy molding compound (EMC) may be used as a resin sealant 43.

The resin sealant 43 is applied onto the upper surface of the circuit substrate strip 30, completely covering the integrated circuit chips 40 and metal wires 41 electrically connecting the integrated circuit chip 40 to the upper surface of each circuit substrate unit area 31. The resin sealant 43 also fills the spaces between neighboring heat slugs. The upper surface of the resin sealant 43 is level with the upper surface of the heat slug 42. Therefore, the cover 42a of the heat slug 42 is exposed outwards through the top of the resin sealant 43, whereas the supporter 42b and the supporter base 42c are sealed by the resin sealant 43.

After group molding is finished, solder balls are formed onto the circuit substrate strip. The circuit substrate strip is divided into individual packages. FIG. 7 is a cross-sectional view illustrating the formation of the solder balls 44 and division of the circuit substrate strip 30 into individual packages. Referring to FIG. 7, after group molding is finished, the circuit substrate strip 30 is turned upside down and the solder balls 44, acting as external terminals of the package, are attached simultaneously to the lower surface (shown facing upwards in the drawing) of the circuit substrate strip 30. The solder balls 44 can be attached through the steps of flux application, attachment of the solder balls 44, and reflow.

Subsequently, the circuit substrate strip 30 is divided along the cutting lines 32 by a cutting tool 45, such as a sawing blade or a laser. Such a cutting process completely divides not only the circuit substrate strip 30 but also the supporter bases 42c and the resin sealant 43. Thereby, the individual package finished in each circuit substrate unit area 31 is separated from the circuit substrate strip 30.

The final structure of the individual package made by the above production method is illustrated in FIG. 8. FIG. 8 is a cross-sectional view of a semiconductor package having a heat slug in accordance with an embodiment of the invention. As shown in FIG. 8, the heat slug 42 is inserted into the resin sealant 43 while the topside of the heat slug is exposed out of the surface of the resin sealant 43. Especially, the heat slug 42 can have almost the same size as the circuit substrate unit area 31, because the resin sealant 43 is applied by group molding.

The shape of the heat slug 42 can be modified, if necessary. FIG. 9 is a cross-sectional view showing another embodiment of a semiconductor package 50a having a heat slug in accordance with the invention.

Referring to FIG. 9, the heat slug 42 has a projection 42d which protrudes from the lower surface of the cover 42a and, thus, links the heat slug 42 to the integrated circuit chip 40. The projection 42d directly contacts the integrated circuit chip and, thereby, can dissipate the heat generated from the integrated circuit chip more efficiently.

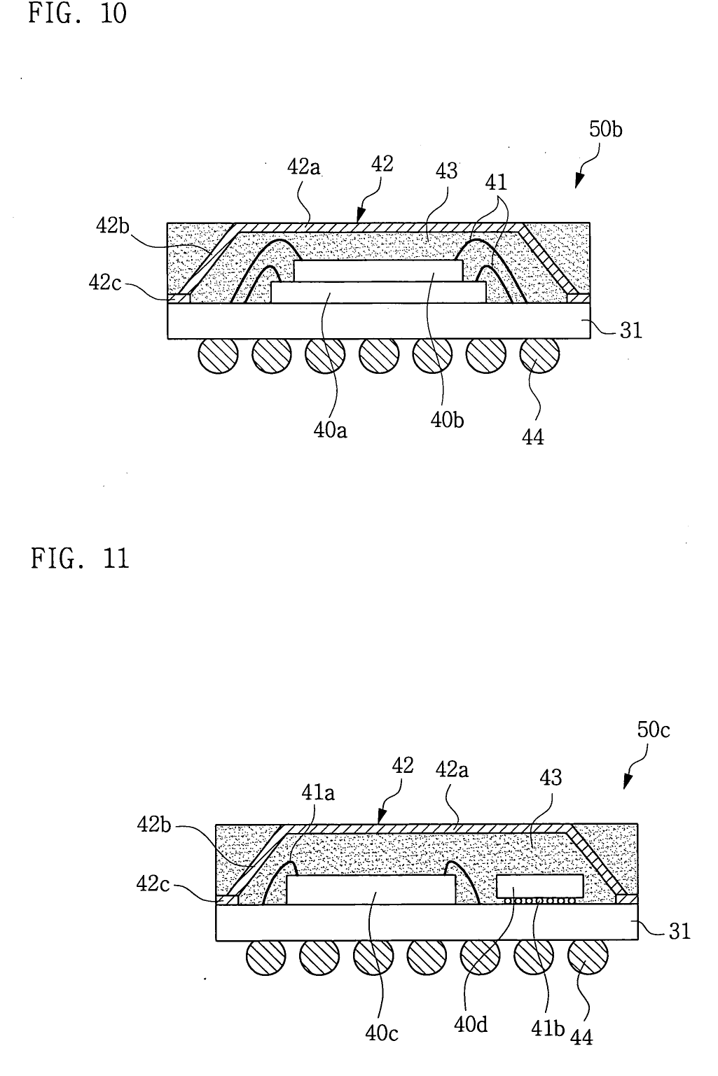

The above embodiments are examples of individual package (50 in FIG. 8 and 50a in FIG. 9) containing only one integrated circuit chip 40. However, the invention can also be utilized for the package type in which two or more integrated circuit chips are included. FIGS. 10 and 11 are cross-sectional views illustrating semiconductor packages (50b and 50c) having a heat slug in accordance with further embodiments of the invention.

As shown in the FIG. 10, the integrated circuit chips (40a and 40b) are stacked vertically and each integrated circuit chip can be connected electrically to the circuit substrate strip 30 through metal wires 41. The package 50b shown in FIG. 10 contains two integrated circuit chips (40a and 40b) of different sizes; however, it can also contain integrated circuit chips of the same size by inserting a spacer between the chips. Explanation for other structures will be omitted because they are almost identical to the aforementioned embodiments.

The semiconductor package 50c shown in FIG. 11 contains two integrated circuit chips (40c and 40d) arranged horizontally. Electrical connections between the integrated circuit chips (40c and 40d) and the circuit substrate 30 can be made either by a wire bonding method using metal wires 41a, or by a flip chip method using metal bumps 41b. Explanation for other structures will be omitted because they are almost identical to the aforementioned embodiments.

As described above, the semiconductor package having a heat slug in accordance with the present invention provides an advantage of optimizing the heat dissipation efficiency, because the heat slug can have almost the same size as the semiconductor package.

In addition, the semiconductor package having a heat slug in accordance with the invention provides another advantage of maximizing the productivity of manufacturing semiconductor packages having heat slug because the heat slugs are attached simultaneously to the circuit substrate strip and the resin sealant is applied by a group molding process, followed by a cutting process to divide the finished circuit substrate strip into individual packages.

Furthermore, the structure of the semiconductor package having a heat slug and the production method thereof in accordance with the invention follow the trend of smaller package size, finer pitch, etc.

Having described exemplary embodiments of the invention, it is noted that modifications and variations can be made by persons skilled in the art in light of the above teachings. Therefore, it is to be understood that changes may be made to embodiments of the invention disclosed that are nevertheless still within the scope and the spirit of the invention as defined by the appended claims.

What is claimed is:

1. A method of manufacturing semiconductor package having a heat slug comprising:
providing a plurality of circuit substrate unit areas in a molding block disposed on a circuit substrate strip, each circuit substrate unit area having upper and lower surfaces;
attaching at least one integrated circuit chip having active and back surfaces onto the upper surface of each circuit substrate unit area, the active surface of the integrated circuit chip electrically connected to the upper surface of each circuit substrate unit area and the back surface attached to the upper surface of each circuit substrate unit area;
attaching a heat slug onto the upper surface of each circuit substrate unit area;
applying resin sealant onto the molding block by a group molding process so as to seal the integrated circuit chip and to have a part of the heat slug exposed outwards;
forming solder balls onto the lower surface of each circuit substrate unit area; and
separating individual semiconductor packages formed on each circuit substrate unit area.

2. The method of claim 1, wherein forming the heat slug comprises:
forming a plurality of supporter bases on the upper surface of each circuit substrate unit area;
connecting the plurality of supporter bases to a plurality of supporters extending from a cover.

3. The method of claim 2, wherein forming a plurality of supporter bases comprises forming a supporter base at corners of the circuit substrate unit area.

4. The method of claim 3, wherein each supporter adjacent to a supporter base is connected to the supporter base.

5. The method of claim 6, wherein connecting the supporter bases and supporters comprises connecting by any one of soldering, conductive epoxy or anisotropic conductive material.

6. The method of claim 2, wherein forming the plurality of supporter bases on the upper surface of each circuit substrate unit area comprises connecting the plurality of supporter bases to a ground pattern of the circuit substrate unit area.

7. The method of claim 1, wherein attaching the solder balls comprises applying flux, attaching the solder balls, and reflowing.

8. The method of claim 1, wherein separating the individual semiconductor packages comprises cutting the circuit substrate strip with a sawing blade or laser.

9. A semiconductor package having a heat slug, comprising:
a circuit substrate strip, having upper and lower surfaces;
at least one integrated circuit chip having active and back surfaces, wherein the active surface is electrically connected to the upper surface of the circuit substrate strip and the back surface is attached to the upper surface of the circuit substrate strip;
a heat slug attached onto the upper surface of the circuit substrate strip;
a sealant disposed onto the circuit substrate strip so as to seal the integrated circuit chip and to have a part of the heat slug exposed outwards; and
solder balls attached onto the lower surface of the circuit substrate strip.

10. The semiconductor package of claim 9, wherein the heat slug comprises a cover and supporters extending from the cover.

11. The semiconductor package of claim 10, wherein the cover is exposed outwards through the upper surface of the sealant and the supporters are sealed in the sealant.

12. The semiconductor package of claim 10, wherein the cover is substantially the same size as the circuit substrate unit area.

13. The semiconductor package of claim 10, wherein the heat slug further comprises supporter bases disposed on the upper surface of the circuit substrate strip.

14. The semiconductor package of claim 13, wherein the supporters are connected to the supporter bases.

15. The semiconductor package of claim 14, wherein the connection between supporter base and supporter is made by any one of soldering, conductive epoxy or anisotropic conductive material.

16. The semiconductor package of claim 13, wherein the supporter base is connected to a ground pattern of the circuit substrate strip.

17. The semiconductor package of claim 10, wherein the heat slug comprises a projection which protrudes from the cover and links the cover to the integrated circuit chip.

18. The semiconductor package of claim 9, wherein the semiconductor package has two or more integrated circuit chips stacked vertically.

19. The semiconductor package of claim 9, wherein the semiconductor package has two or more integrated circuit chips arranged horizontally.

20. The semiconductor package of claim 9, wherein the electrical connection of the integrated circuit chip is made with a metal wire or a metal bump.
